(19) United States
(12) Patent Application Publication
(10) Pub. No.: US 2020/0309857 A1
(43) Pub. Date: Oct. 1, 2020

(54) METHODS, SYSTEMS, AND DEVICES FOR ESTIMATING AND PREDICTING BATTERY PROPERTIES

(71) Applicant: EnerSys Delaware Inc., Reading, PA (US)

(72) Inventors: Samane Zeyghami, Reading, PA (US); Alessandro Capellini, Reading, PA (US)

(21) Appl. No.: 16/366,029

(22) Filed: Mar. 27, 2019

(51) Int. Cl. G01R 31/367; G01R 31/371; G01R 31/374

(52) U.S. Cl. CPC G01R 31/367; G01R 31/374; G01R 31/371

(57) ABSTRACT

Methods, systems, and devices that include improvements to determining properties of a battery are described. For example, a method may include measuring one or more properties of a battery; determining a charging status of the battery based on the measured one or more properties; and updating one or more predictions of properties of the battery based on the determined charging status of the battery, wherein the one or more predictions comprises a prediction of a remaining time to charge the battery and/or a prediction of a remaining time to discharge the battery, resulting in updated one or more predictions of the properties of the battery.

### TECHNICAL FIELD

The present disclosure relates to batteries, and in particular, to methods, systems, and devices for estimating and predicting battery properties, such as state of charge (SOC).

### BACKGROUND

Batteries have become increasingly important, with a variety of industrial, commercial, and consumer applications. Of particular interest are power applications involving “deep discharge” duty cycles, such as motive power applications. The term “deep discharge” refers to the extent to which a battery is discharged during service before being recharged. By way of counter example, a shallow discharge application is one such as starting an automobile engine wherein the extent of discharge for each use is relatively small compared to the total battery capacity. Moreover, the discharge in such shallow discharge cases is followed soon after by recharging. Over a large number of repeated cycles very little of the battery capacity is used prior to recharging.

Conversely, deep discharge duty cycles are characterized by drawing a substantial majority of the battery capacity before the battery is recharged. Some motive power applications that require deep cycle capability include Class 1 electric rider trucks, Class 2 electric narrow isle trucks and Class 3 electric hand trucks. Desirably, batteries installed in these types of vehicles must deliver a number of discharges during a year that may number in the hundreds. The cycle life of batteries used in these applications typically can range from 500-2000 total cycles so that the battery lasts a number of years before it needs to be replaced.

Interest and research in batteries has resulted in a variety of battery chemistries, with differing benefits and drawbacks. For example, “flooded” lead-acid batteries tend to be more economical, but may require periodic maintenance that includes replenishment of an electrolyte, which can spill; such batteries may also have reduced capacity over time resulting from liberation of acid during charging. Alternative lead-acid batteries may use a gelled electrolyte, which cannot spill and avoid the acid liberation problem, but have their own drawbacks in that the internal resistance may be higher, limiting the ability of such batteries to deliver high currents. Still other types of batteries include lithium-ion or lithium ion polymer batteries, nickel-cadmium, nickel-metal hydride, and others. The benefits and drawbacks of such battery types are known to those in the art and need not be discussed here.

Regardless of the type of battery used in an application, two important properties of a given battery at a given point in time during usage is how much operating time is left before a charge is required, as well as how much charging time is needed for a “full” battery.

Common techniques for providing these measurements suffer from inaccuracy errors. For example, the state of charge of the battery (or of the cells of a multi-cell battery) may be used, which may be defined as an available capacity of a battery (measured in ampere-hours, Ah) as a percentage of a rated capacity of the battery. For example, a state of charge (SOC) of a “full” battery may be 100%, and a SOC of an empty battery may be 0%. In known techniques, the SOC at a given point in time may be simply multiplied by a default usage rate to provide an estimation of discharge time remaining, or by a default charging rate to provide an estimation of charging time remaining.

### SUMMARY

SOC is difficult to measure directly, and instead it is typically estimated from direct measurement variables. A common technique is simple coulomb counting, which measures battery charge and discharge current and integrates in time. Although measurements of current used in coulomb counting may be precise, simple coulomb counting may be subject to error. Further, it has been recognized by the inventors of this application that known techniques for estimating discharge time remaining and charge time remaining suffer from inaccuracy errors as well, as usage rates and/or charging rates are highly variable and/or non-linear.

Accordingly, the present disclosure and the inventive concepts described herein provide methods, systems, and devices for predicting a future SOC of a battery as a function of a usage pattern, as well as predicting usage-adaptive remaining run time and recharge time. Additionally, the present disclosure and the inventive concepts described herein provide methods, systems, and devices to monitor more accurately a state of charge of a battery using an enhanced coulomb counting technique. The inventive concepts described herein are combinable and provide more accurate monitoring and predicting in a variety of applications, including motive power applications. Furthermore, the inventive concepts herein have separate utility in various applications where prediction and/or estimation of SOC of a battery at a present point in time or a future point of time is desired.

For example, provided herein are methods, systems, and devices that include improvements to determining properties of a battery. For example, a method may include measuring one or more properties of a battery; determining a charging status of the battery based on the measured one or more properties; and updating one or more predictions of properties of the battery based on the determined charging status of the battery, wherein the one or more predictions comprises a prediction of a remaining time to charge the battery and/or a prediction of a remaining time to discharge the battery, resulting in updated one or more predictions of the properties of the battery.

### BRIEF DESCRIPTION OF THE DRAWINGS

The accompanying drawings, which are incorporated in and constitute a part of the specification, illustrate embodiments of the inventive concepts and, together with the description, serve to explain principles of the inventive concepts.

FIG. 1 is a schematic block diagram illustrating an example battery monitoring system according to some embodiments of the present inventive concepts.

FIG. 2 is a flowchart of an example battery monitoring method according to some embodiments of the present inventive concepts.

FIG. 3 is a flowchart of an example method for predicting a charging time for a battery according to some embodiments of the present inventive concepts.

FIG. 4 is a flowchart of an example method for predicting a discharging time of a battery according to some embodiments of the present inventive concepts.

FIG. 5 is a flowchart of an example method for performing calibration of variables used in monitoring a battery according to some embodiments of the present inventive concepts.

FIG. 6 is a schematic block diagram of various components of a computing device, which may be used in the implementation of one or more of the devices of the battery monitoring system of FIG. 1, as well as other devices discussed herein.

FIG. 7A is a plot of charging current in a battery over time, and FIG. 7B is a plot of a predicted time remaining vs true time remaining at points in the plot of FIG. 7A according to some embodiments of the present inventive concepts.

FIG. 8A is a plot of discharging current in a battery over time, and FIG. 8B is a plot of a predicted time remaining vs true time remaining at points in the plot of FIG. 8A according to some embodiments of the present inventive concepts.

### DETAILED DESCRIPTION

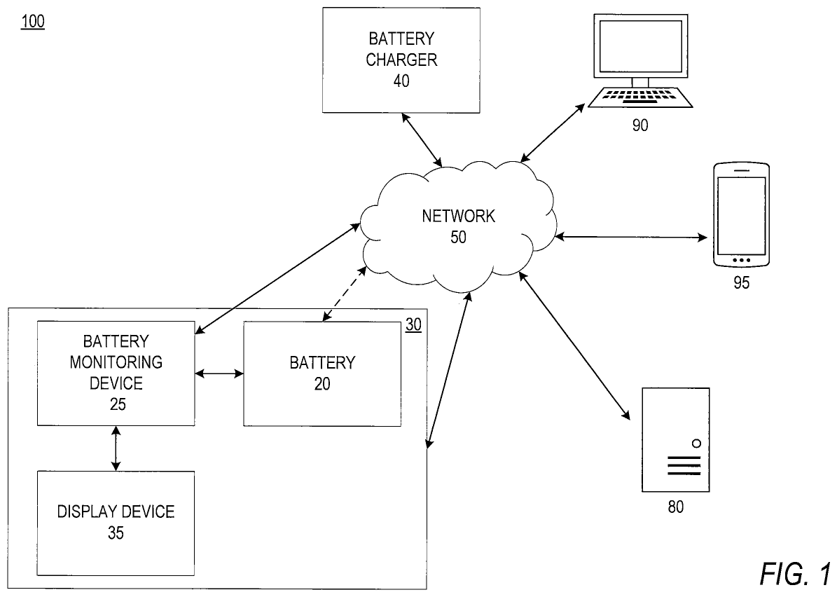

FIG. 1 illustrates an example battery monitoring system 100 in which battery 20 is monitored by one or more components, including for example battery monitoring device 25.

The phrase “battery monitoring” as used herein may include measuring values of properties of a battery at a point in time and/or over a period of time. “Battery monitoring” may also include estimating values of battery properties at past and/or present points in time, relative to a time when the estimation is performed. For example, a property may be estimated where the property is difficult, time-consuming, or energy-consuming to measure directly. First and second values measured at first and second points in time, respectively, may be used to estimate a third value at a third point in time occurring in between the first and second points in time. “Battery monitoring” may also include predicting future values of battery properties at a point in time in the future relative to when the prediction is made. Such predicted future values may be based on one or more measured and/or estimated values of properties of the battery, at points in time at and/or before when the prediction is made. Example properties that may be measured, estimated, and/or predicted may include current (e.g., current flowing to the battery, current flowing from the battery), voltage (e.g., open-circuit voltage, voltage applied to load), battery temperature, battery state of charge, time remaining to charge, time remaining to discharge, and so on. Measured, estimated, and/or predicted battery properties may be based on other measured, estimated, and/or predicted properties of the battery. Other data or information available within the battery monitoring system 100 may also be used to measure, estimate, and/or predict battery properties, such as models of complex battery properties, stored history of battery usage data, and so on.

The battery 20 may be of any type compatible with the present disclosure, with examples including lead-acid batteries, lithium-ion batteries, and so on. The battery 20 may have one or more local sensors (not shown in FIG. 1) to detect one or more characteristics or properties of the battery 20, such as current, voltage, and/or temperature. For example, a current sensor may be used to sense current flowing to the battery 20 and/or current flowing from the battery 20; a voltage sensor may be used to sense a voltage of the battery 20 (such as under load or open-circuit); and/or a thermal sensor may be used to sense a temperature of the battery 20. Such sensors may be integrated into the battery 20 or present within the battery monitoring system 100 at location(s) relatively proximate to the battery 20. In some embodiments, the sensors may be within the battery monitoring device 25.

As illustrated in FIG. 1, the battery 20 may be used by a vehicle 30 in operation thereof. The battery monitoring device 25 may be located relatively proximate to the battery 20 (e.g., within the vehicle 30) or may be relatively remote from the battery (e.g., not within the vehicle 30). In some embodiments, the battery 20 may be detachable or disconnectable from the vehicle 30. The battery 20 may be configured to be temporarily attachable to a charger 40 for charging thereof. The charger 40 may be of any type compatible with the present disclosure and may be configured to provide a charging current to batteries of one or more types.

The battery monitoring device 25 may be electrically and/or communicatively coupled to the battery 20 and configured to receive measurements from the sensors of battery 20 and/or the sensors of the battery monitoring device 25 and communicate the measurements to one or more recipients. Estimations and/or predictions of battery properties based on the measurements may also be communicated. Examples of recipients may include a user of the vehicle 30 in which the battery 20 is installed. Data may be communicated (e.g., graphically, tabularly, and/or numerically) to the user of the vehicle 30 via an user interface, such as a display device 35 mounted in a dashboard of the vehicle 30 or otherwise visible to the user during operation of the vehicle 30. Other examples of recipient may be computing devices 90 and 95, which may communicate with the battery monitoring device 25 over a network 50, and which may be smartphones, tablets, desktop computers, laptop computers, thin clients, mainframes, servers, and so on. The computing devices 90 and 95 may be running software configured to receive the data and/or other values from the battery 20 and/or the battery monitoring device 25 and perform one or more actions based thereon. As an example of such actions, the computing device 90 may be configured to receive data and/or other values from the battery 20 and/or the battery monitoring device 25, determine a notification (e.g., a notification of a SOC of the battery 20, a notification of a remaining run time of the battery 20) should be sent to the computing device 95, and cause transmission of the notification to the computing device 95, for example via the network 50. In some embodiments, the battery monitoring device 25 may be integrated with the battery 20. In some embodiments, the battery monitoring device 25 may be integrated with the vehicle 30 and/or the charger 40.

In some embodiments, sensed values of properties, estimations of values of properties, and/or predictions of values of properties may be stored in a database at database server 80. The database server 80 may be a part of any of the computing devices of FIG. 1, the battery monitoring device 25, and/or a separate device as illustrated.

In some embodiments, functionality described herein as being performed by the battery monitoring device 25 may be performed additionally or alternatively by one or more of the computing devices 90, 95 in the battery monitoring system 100 of FIG. 1. For example, proximate to the battery 20 may be sensors, which may sense properties of the battery 20 and communicate the sensed properties over the network 50 to one or more of the computing devices 90, 95, as indicated by the dashed arrow between the battery 20 and the network 50. The computing devices 90, 95 may analyze the communicated sensed properties and perform one or more estimations and/or predictions. In some embodiments, all or part of the battery monitoring device 25 may overlap with one or more of the devices of the battery monitoring system 100 of FIG. 1, including the computing devices 90, 95 or the database server 80.

The battery 20, the battery monitoring device 25, the charger 40, and/or the computing devices 90, 95 may include a display device for displaying measurements, estimations, and/or predictions (e.g., graphically, tabularly, and/or numerically). In some embodiments, the battery 20, the battery monitoring device 25, the charger 40, and/or the computing devices 90, 95 may include input devices configured to accept user input, such as an initial state of charge of the battery 20, desired type of output/display, user settings (e.g., temperature values provided in Celsius or Fahrenheit) and so on.

The network 50 may include a local network, a wireless, coaxial, fiber, or hybrid fiber/coaxial distribution system, a Wi-Fi or Bluetooth network, or any other desired network. The network 50 may be made up of one or more subnetworks, each of which may include interconnected communication links of various types, such as coaxial cables, optical fibers, wireless links, and the like. The network 50 and/or the subnetworks thereof may include, for example, networks of Internet devices, telephone networks, cellular telephone networks, fiber optic networks, local wireless networks (e.g., WiMAX, Bluetooth), satellite networks, and any other desired network, and each device of FIG. 1 may include the corresponding circuitry needed to communicate over the network 50, and to other devices on the network. Although the devices of the battery monitoring system 100 of FIG. 1 are illustrated as communicating over a common network 50, in some embodiments various point-to-point or device-to-device networks or communication links may be used in addition to or alternatively from the common network 50 for example to communicate data between a first device (e.g., the battery monitoring device 25) and a second device (e.g., the computing device 95). Furthermore, although each component of the illustrated battery monitory system 100 is shown as directly connected to the network 50 in FIG. 1, in some embodiments devices may be

Returning to the battery monitoring device 25, the battery monitoring device 25 may be configured to perform one or more methods to provide an estimation and/or a prediction of a SOC of the battery 20, a remaining run time of the battery 20, and/or a recharge time of the battery 20. For example, the remaining run time of the battery 20 may be a function of the remaining capacity of the battery 20 and the rate of usage of the charge of the battery 20. The rate of usage may be variable in many applications. For example, in motorized vehicles, such as electric rider trucks, electric narrow isle trucks, or electric hand trucks, the rate of usage of a battery 20 may be dependent on one or more of a mass of the motorized vehicle and/or a load carried by the motorized vehicle, an operating speed of the motorized vehicle, characteristics of a motor of the motorized vehicle, an ambient temperature in a location where the motorized vehicle is operated, and so on. Additionally, the capacity of the battery can be a function of the usage pattern. For example, Peukert's Law provides that

$$t = {H ( \frac{C}{IH} )}^{k} \qquad ( 1 )$$

where H is the rated discharge time of the battery 20 (provided by the manufacturer), C is the rated capacity (in Ah), I is the actual usage, k is a constant dependent on the type of battery 20, typically between 1.0 and 1.5, and t is the time in hours that the battery 20 will last at the increased current I. Increased usage of the battery above the rated capacity will result in a lower time t, and decreased usage of the battery below the related capacity will result in a greater time t. The variability and interrelation of usage rate and rated capacity may make prediction of the remaining run time difficult.

The time needed to recharge the battery 20 may also be a difficult value to predict, as the charge acceptance of the battery 20 may exhibit nonlinear behavior. The recharge time may be a function of several parameters, including rate of charge, battery voltage, temperature, and/or other parameters.

The prediction accuracy of both a remaining run time prediction and a recharge time prediction depend on accurate knowledge of the SOC of the battery 20 at a time when such predictions are made. It is recognized by the present inventors that charge inefficiencies are not considered in the known coulomb counting techniques. Charge inefficiencies, that is, inefficiencies in charge acceptance by the battery 20, may be based on rate of charge and/or temperature of the battery 20.

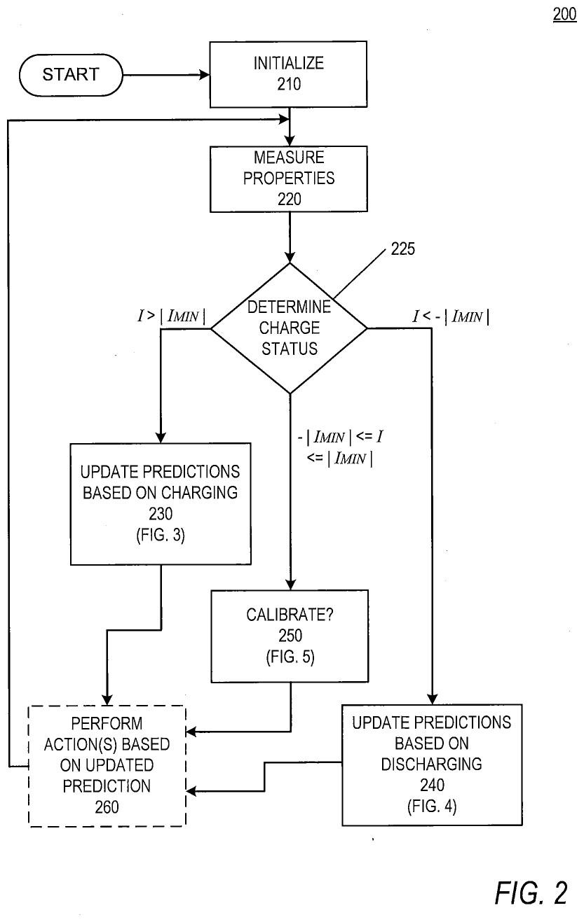

FIG. 2 is a flowchart of an example battery monitoring method 200 according to some embodiments of the present inventive concepts. The battery monitoring method 200 may be performed by one or more devices of the battery monitoring system 100 of FIG. 1, such as the battery monitoring device 25 to estimate and/or predict one or more values of properties of the battery 20.

As illustrated in FIG. 2, the battery monitoring method 200 may include an initialization operation 210, which may be performed for the battery 20 once as illustrated in FIG. 2, and/or may be performed periodically for the battery 20 based on user preference or responsive to an indication, such as expiration of a timer, an indication that the battery 20 has been idle for a period of time, or so on. During initialization operation 210, an initial SOC of the battery 20 may be known (e.g., retrieved from a memory device) and/or may be inputted by a user. In some embodiments, an initial SOC of the battery 20 may be unknown and/or not entered by the user, and in such embodiments, the initial SOC may be determined based on a measurement of an open circuit voltage (OCV) after a period of time where the battery is idle. The length of the period of time may be dependent on the type or chemical properties of the battery, and may be (as an example) between 1-4 hours to permit relaxation of the battery 20. From the open circuit voltage, the initial SOC may be determined, for example using a curve or relationship between SOC and OCV. The initial SOC determined in this manner may then be stored in a memory device. Additional battery properties may be determined or estimated from the initial SOC, whether the SOC determined from OCV, received from memory, or inputted by a user. Such properties may include, in some embodiments, a remaining capacity of the battery (in Ah units), as well as initial predictions of the time remaining to charge and time remaining in discharge. The remaining capacity of the battery 20 may be determined from a product of the initial SOC with a nominal capacity of the battery 20, which may be retrieved from a memory device. The initial prediction of the remaining time to charge may be determined from the initial SOC and a default time to completely charge the battery 20, as provided from a manufacturer of the battery 20 and/or based on empirical data collected for the battery 20 or the type of the battery 20. The initial prediction of the remaining time to discharge the battery 20 may be determined from the initial SOC and a nominal usage rate (in units of current) for an application (e.g., Class 1 electric rider trucks, Class 2 electric narrow isle trucks and Class 3 electric hand trucks). The application may be provided as input to the battery monitoring device 25, or a default application (and hence a default nominal usage rate) may be used in the initialization operation 210.

In operation 220, one or more properties of the battery may be measured at a first point in time (t₁), using the sensors of the battery 20 and/or of the battery monitoring device 25 as discussed above. Examples of measured battery properties may include voltage, current, and temperature. In operation 225, the charge status of the battery 20 may be determined, for example, based on a flow of current to or from the battery 20. Herein, a flow of current to the battery (e.g., a charging current) may be referred to as a positive current, and a flow of current from the battery (e.g., a discharging current) may be referred to as a negative current.

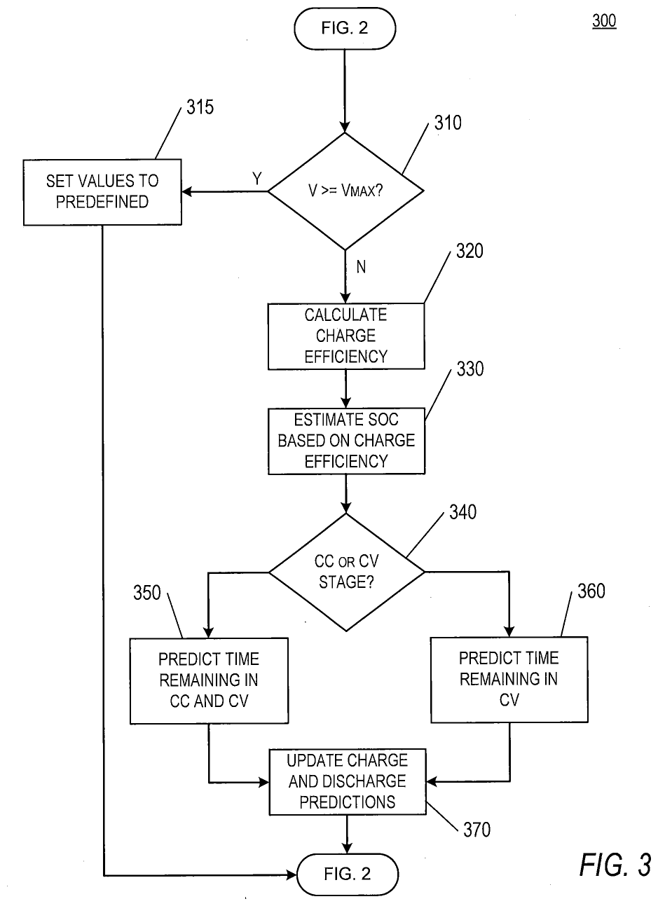

In operation 225, if a measured current is greater than a first current threshold |I_{MIN}|, then the battery 20 may be charging, and operation 230 may be performed, where one or more predictions, such as a remaining time to charge, are updated. For example, the initial prediction of the remaining time to charge the battery 20, or a previous prediction of the remaining time to charge the battery 20, may be updated in operation 230. Additionally and/or alternatively in operation 230, a prediction of the remaining time to discharge may be updated, as the current flowing to the battery 20 may result in increased charge in the battery 20, increasing the remaining capacity. Accordingly, the initial prediction of the remaining time to discharge the battery 20, or a previous prediction of the remaining time to discharge the battery 20, may be updated in operation 230. Further details of operation 230 are provided with reference to FIG. 3.

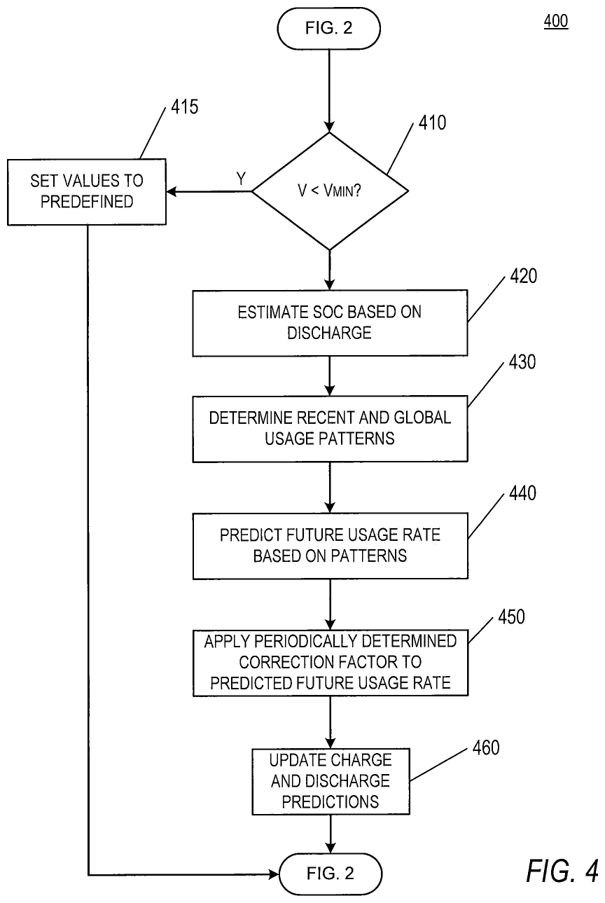

In operation 225, if the measured current is less than a second current threshold −|I_{MIN}|, then the battery 20 may be discharging, and operation 240 may be performed, where one or more predictions, such as a remaining time to discharge, are updated. For example, the initial prediction of the remaining time to discharge the battery 20, or a previous prediction of the remaining time to discharge the battery 20, may be updated in operation 240. Additionally and/or alternatively in operation 240, a prediction of the remaining time to charge may be updated, as the current flowing from the battery 20 may result in decreased charge in the battery 20, decreasing the remaining capacity. Accordingly, the initial prediction of the remaining time to charge the battery 20, or a previous prediction of the remaining time to charge the battery 20, may be updated in operation 240. Further details of operation 240 are provided with reference to FIG. 4.

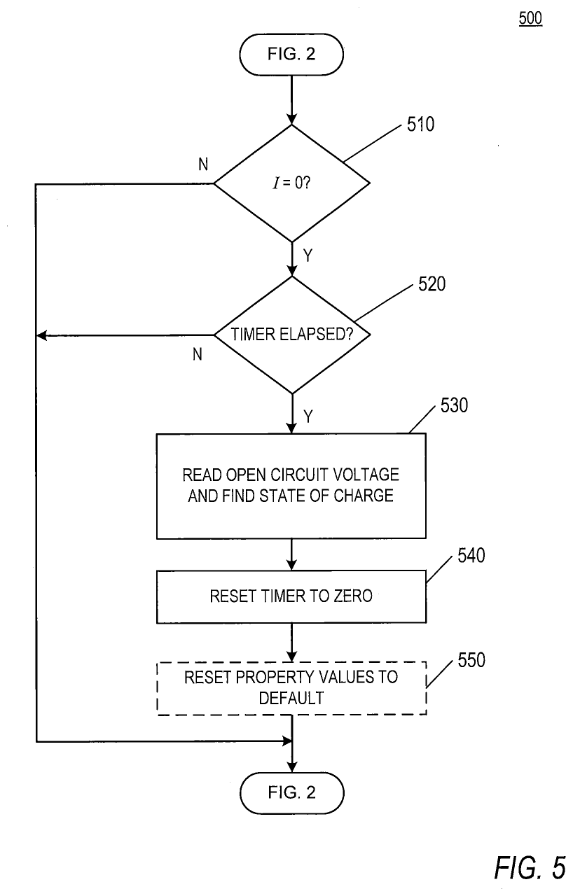

In operation 225, if the measured current is greater than the second current threshold −|I_{MIN}| and less than the first current threshold |I_{MIN}| (e.g., the measured current is proximate to zero), then the battery 20 may be idle and then operation 250 may be performed. Operation 250 may be a periodic calibration operation that includes sub-operations similar to those discussed with respect to the initialization operation 210. Further details of operation 250 are provided with reference to FIG. 5.

After performance of one of operations 230, 240, or 250, optionally operation 260 may be performed, in which one or more actions are taken, for example based on the updated predictions and/or estimations of values determined in the performed operation 230, 240, or 250. Such actions may include, for example, transmitting a notification to a user or a device (e.g., the display device 35 of the vehicle 30, the computing devices 90, 95, the database 80) indicating the updated predictions and/or estimations of values determined in the performed operation 230, 240, or 250. As another example, a reservation may be made at the battery charger 40 to charge the battery 20 at a point in time based on the updated predicted discharge time of the battery 20.

The method 200 may then return to operation 220 and perform another measurement of one or more of the properties of battery 20, as discussed above, for a second point in time (t₂). As an example, a measurement of one or more of the properties of battery 20 may occur once every second, multiple times a second, or periodically every n seconds, where n>=2. In some embodiments, operations 225, 230, 240, 250, and/or 260 may also be performed once every second, multiple times a second, or periodically every n seconds, where n≥2. In some embodiments, operations 225, 230, 240, 250, and/or 260 may be performed at a different rate than the measurement of the one or more properties of the battery 20, and at different rates from each other. For example, operation 230, 240, or 250 may be performed less frequently than operation 220 or 225, and operation 260 may be performed less frequently than operation 230, 240, or 250.

Reference is now made to FIG. 3, which is a flowchart of an example method 300 for predicting a charging time for a battery according to some embodiments of the present inventive concepts. In some embodiments, example method 300 may be performed at operation 230 of FIG. 2, although the present disclosure is not limited thereto.

In operation 310, the voltage of the battery 20 (which was measured, for example, in operation 220 of FIG. 2) may be compared with a threshold maximum voltage V_{MAX}. If the voltage is greater than or equal to V_{MAX} (e.g., YES branch from operation 310), then the battery 20 may be considered charged, and predefined values may be used in operation 315. For example, the SOC of the battery may be set to “full” or 100%, the capacity of the battery may be set to the nominal capacity of the battery (which may be provided by the manufacturer of the battery 20), the remaining time to charge may be set to zero, and the remaining time to discharge may be based on the nominal capacity of the battery and the nominal usage of the battery in a given application, such as whether the battery 20 will be used in e.g., Class 1 electric rider trucks, Class 2 electric narrow isle trucks, or Class 3 electric hand trucks. As discussed above, a specific application for the battery 20 may be provided as input to the battery monitoring device 25, or a default application may be used.

If, however, the voltage is not greater than V_{MAX} (e.g., NO branch from operation 310), then a charge efficiency may be calculated in operation 320. The charge efficiency may be calculated based on the initial SOC or a previously estimated SOC, the measured current, and the measured temperature of the battery 20 (which were measured, for example, in operation 220 of FIG. 2). The charge efficiency may be a value between 0 and 1, representing that the measured current may result in only a partial charge based on the charge efficiency. In operation 330, the SOC of the battery 20 may be updated. For example, the initial SOC of battery 20, or a previous SOC of the battery 20, may be updated in operation 330 by first calculating a relative change in capacity (Ah) based on the measured current and Δt, the difference in time between the present measurement of the current and the previous measurement of the current. This relative change in capacity is then summed with the present estimated capacity of the battery 20, resulting in a new estimated capacity of the battery 20. An updated SOC is determined based on the new estimated capacity of the battery 20, and the nominal capacity of the battery (provided by the manufacturer or determined empirically).

In operation 340, the battery monitoring device 25 may determine whether the battery 20 is in a constant current (CC) or a constant voltage (CV) charging stage. In charging profiles where multiple charging stages are used, a CC stage may be used until a pre-set voltage level is reached. The battery 20 and/or the charger 40 may then switch to the CV stage and decrease the current as the charge approaches completion. To determine whether the battery 20 is in the CC or CV charging stage, a magnitude of the measured voltage of the battery 20 at a present point in time is used, as is average measured voltage over the past x seconds. In some embodiments, x may be between 5 seconds and 60 seconds, as examples. If a difference between the magnitude of the measured voltage and the average voltage is greater than a predetermined threshold, then the battery 20 is in the CC stage, and the method 300 may proceed to operation 350. If the difference between the magnitude of the measured voltage and the average voltage is less than or equal to the predetermined threshold, then the battery 20 is in the CV stage, and the method 300 may proceed to operation 360.

In operation 350, the battery monitoring device 25 may predict the time remaining to charge in the CC stage as well as the predicted time to charge in the CV stage when that stage is reached. In some embodiments, the SOC of the battery 20, as well as the measured current of the battery are used as inputs to a CC pre-trained multi-variable model, which predicts how much energy will be accepted by the battery 20 before the voltage of the battery rises to the maximum charge voltage, and consequently the battery 20 switches to the CV stage. The CC pre-trained multi-variable model may be stored in memory within the battery monitoring device 25 and/or elsewhere within the battery monitoring system 100. In some embodiments, the CC pre-trained multi-variable model may be further dependent on a type of the battery 20. Different CC pre-trained multi-variable models may be available to the battery monitoring device 25, and a CC pre-trained multi-variable model may be selected from the different CC pre-trained multi-variable models based on a type of the battery 20, a user preference, or the like. The output of the CC pre-trained multi-variable model (e.g., the CC selected pre-trained multi-variable model) may be used to estimate the duration of the CC stage, resulting in a value T_{CC}. A predicted SOC at the end of the CC stage (SOC_{CC} may also be determined).

Continuing in operation 350, the time of the CC stage (e.g., T_{CC}) and the predicted SOC at the end of the CC stage (e.g., SOC_{CC}) may be used as inputs to predict the duration of the CV stage, using a CV pre-trained multi-variable model may be stored in memory within the battery monitoring device 25 and/or elsewhere within the battery monitoring system 100. In some embodiments, the CV pre-trained multi-variable model may be further dependent on a type of the battery 20. Different CV pre-trained multi-variable models may be available to the battery monitoring device 25, and a CV pre-trained multi-variable model may be selected from the different CV pre-trained multi-variable models based on a type of the battery 20, a user preference, or the like. The output of the CV pre-trained multi-variable model (e.g., the selected CV pre-trained multi-variable model) may be used to estimate the duration of the CV stage, resulting in a value T_{CV}. The predicted time remaining in charge (e.g., to fully charge) may be based on the predicted duration of the CC stage (T_{CC}) and the predicted duration of the CV stage (T_{CV}), less the time the battery 20 has already spent in charging, which may be stored in memory in the battery monitoring device 25.

An initial prediction of the remaining time to charge the battery 20, or a previous prediction of the remaining time to charge the battery 20, may be updated in operation 370 based on the result of operation 350, that is, using the predicted time remaining in charge (e.g., to fully charge) based on the predicted duration of the CC stage (T_{CC}) and the predicted duration of the CV stage (T_{CV}), less the time the battery 20 has already spent in charging. Additionally and/or alternatively in operation 370, a prediction of the remaining time to discharge may be updated, as the current flowing to the battery 20 may result in increased charge in the battery 20, increasing the remaining capacity. For example, the new estimated capacity of the battery 20 may be used to calculate a new time to discharge the battery 20. Accordingly, the initial prediction of the remaining time to discharge the battery 20, or a previous prediction of the remaining time to discharge the battery 20, may be updated in operation 370.

In some embodiments, an updated prediction of the time remaining to fully charge may only be calculated if the rate of charge, which is based on the measured current, changes by an amount greater than a threshold. For example, if the change in current is greater than 5%, an updated prediction of the time remaining to fully charge may be calculated, and if the change in current is not greater than 5%, the updated prediction of the time remaining to fully charge may not be calculated. This may preserve resources, as once the predicted duration of the CC stage (T_{CC}) and the predicted duration of the CV stage (T_{CV}) are calculated, the values may not significantly change absent a change in the measured current. Thus, some performances of operation 350 and 370 may refrain from new predictions of the durations of the CC stage (T_{CC}) and of the CV stage (T_{CV}) and instead decrement the previously predicted time remaining by the increase in time that the battery 20 has already spent in charging.

If the battery monitoring device 25 determines that the battery 20 is in the CV stage at operation 340, then at operation 360, a predicted time remaining in the CV stage is determined. The time of the CC stage (e.g., T_{CC}) and the SOC at the end of the CC stage (e.g., SOC_{CC}) may be used as inputs to predict the duration of the CV stage, using a CV pre-trained multi-variable model may be stored in memory within the battery monitoring device 25 and/or elsewhere within the battery monitoring system 100, which may be selected from a plurality of pre-trained multi-variable models as discussed above.

In some embodiments, during operation 360 a refinement calculation is made to the duration of the CV stage predicted by the CV pre-trained multi-variable model based on a rate of decay in the current over time. As discussed above, the voltage is held relatively constant in the CV stage, and the current may decrease as charge nears completion. To predict the rate of decay, the following equation may be used:

$$λ = \frac{ln ( I ) - ln ( {I}_{0} )}{Δ t} \qquad ( 2 )$$

In Equation (2), I is the most recent current measured, I₀ is the current at the end of the CC stage, and Δt is a duration in time between the measurement time of I₀ and I, with ln being the natural log function. A refinement to the duration of the CV stage (T′) is calculated as follows:

$$\begin{matrix}{T}^{′} = \frac{β ln ( 2 )}{λ} & ( 3 ) \\ {T}_{C V} = \frac{{T}_{CV 1} + T ′}{2} & ( 4 )\end{matrix}$$

In Equation (3), β is a constant that may be determined based on a type of the battery 20 and/or based on charge test data. In Equation (4), T_{CV1} is the duration of the CV stage predicted by the CV pre-trained multi-variable model.

The result of Equation (4) and of operation 360 is used in operation 370 to update an initial prediction of the remaining time to charge the battery 20, or a previous prediction of the remaining time to charge the battery 20. That is, a prediction of the remaining time to charge the battery 20 is updated using the predicted duration of the CV stage (T_{CV}), less the time the battery 20 has already spent in charging in the CV stage. Additionally and/or alternatively in operation 370, a prediction of the remaining time to discharge may be updated, as the current flowing to the battery 20 may result in increased charge in the battery 20, increasing the remaining capacity. For example, the new estimated capacity of the battery 20 may be used to calculate a new time to discharge the battery 20. Accordingly, the initial prediction of the remaining time to discharge the battery 20, or a previous prediction of the remaining time to discharge the battery 20, may be updated in operation 370.

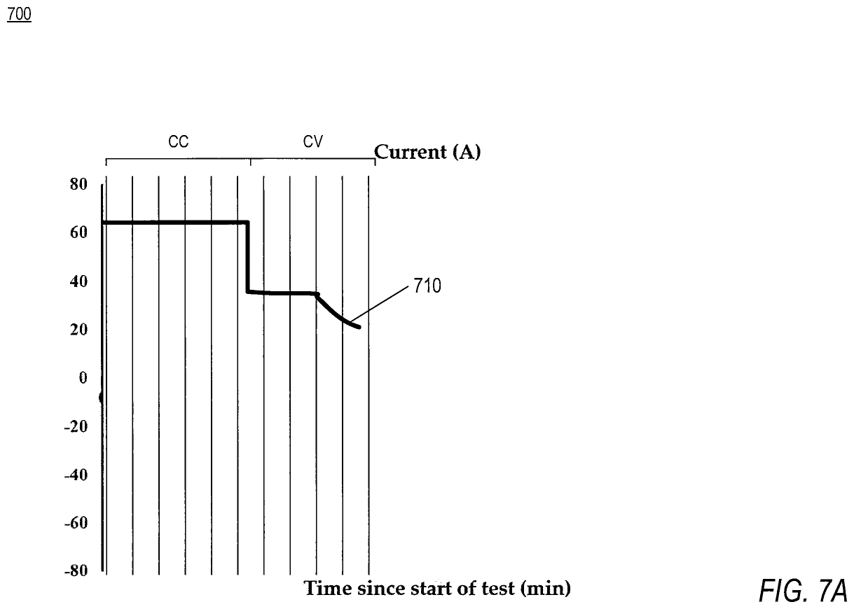

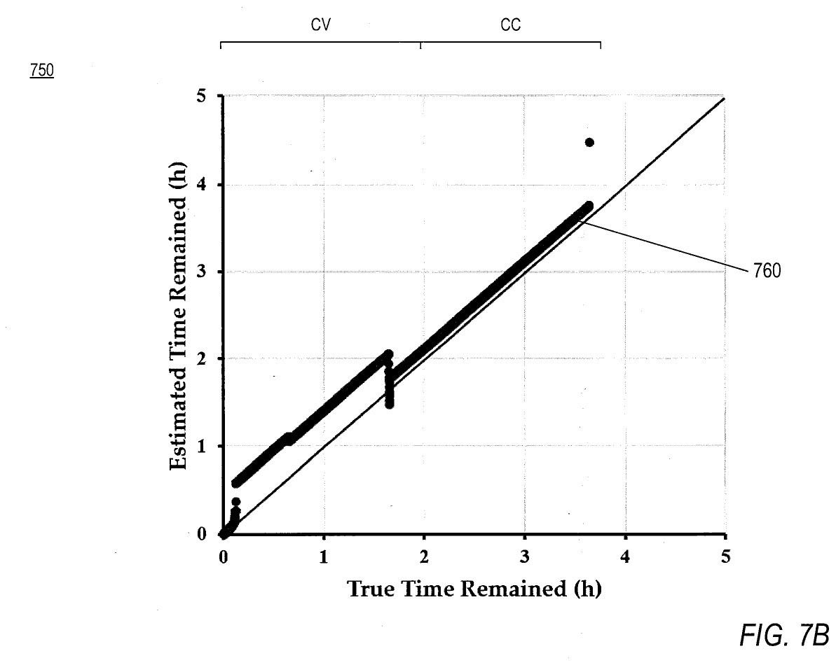

An example performance of the method 300 of FIG. 3 is illustrated in FIGS. 7A and 7B. As seen in plot 700 of FIG. 7A, a charge may be applied to a battery (e.g., the battery 20) over a period of time, resulting in curve 710, which has constant current (in Amps) during a first portion CC and a constant voltage with variable current in a second portion CV. FIG. 7B, a plot of estimated time remaining vs. true time remaining at points during a test resulting in plot 700 of FIG. 7A. In FIG. 7B, time is increasing toward the origin along the line y=x, and thus an ideal prediction system would result in y=x at all given points in time (e.g., an ideal predictive system would estimate 4 hours are remaining in charge at a time when there are actually 4 hours remaining in charge). As illustrated by curve 760, the method 300 of FIG. 3 predicts during first portion CC a time remaining in charge (e.g., to fully charge) based on the predicted duration of the CC stage (T_{CC}) and the predicted duration of the CV stage (T_{CV}), less the time the battery 20 has already spent in charging. When the battery 20 switches to CV, a predicted time remaining in the CV stage is determined. The time of the CC stage (e.g., T_{CC}) and the SOC at the end of the CC stage (e.g., SOC_{CC}) may be used as inputs to predict the duration of the CV stage. Furthermore, as discussed above, a refinement may be made to the predicted duration of the CV stage based on the rate of decay of the current. This refinement is best seen near the origin of plot 750 of FIG. 7B.

Reference is now made to FIG. 4, which is a flowchart of an example method 400 for predicting a remaining time in discharge for a battery according to some embodiments of the present inventive concepts. In some embodiments, example method 400 may be performed at operation 240 of FIG. 2, although the present disclosure is not limited thereto.

In operation 410, the voltage of the battery 20 (which was measured, for example, in operation 220 of FIG. 2) may be compared with a threshold minimum voltage V_{MIN}. If the voltage is less than V_{MIN} (e.g., YES branch from operation 410), then the battery 20 may be considered charged, and predefined values may be used in operation 415. For example, the SOC of the battery may be set to “empty” or 0%, the capacity of the battery may be set to zero, the remaining time to charge may be set to the nominal charge time (supplied by the manufacturer of the battery 20), and the remaining time to discharge may be set to zero.

If, however, the voltage is not less than V_{MIN} (e.g., NO branch from operation 410), then in operation 420, the SOC of the battery 20 may be updated. For example, the initial SOC of battery 20, or a previous SOC of the battery 20, may be updated in operation 420 by first calculating a relative change in capacity (Ah) based on the measured current and Δt, the difference in time between the present measurement of the current and the previous measurement of the current. This relative change in capacity (which may be negative, as the current is flowing from the battery 20 in discharge) is then summed with the present estimated capacity of the battery 20, resulting in a new estimated capacity of the battery 20. An updated SOC is determined based on the new estimated capacity of the battery 20 and the nominal capacity of the battery (provided by the manufacturer or determined empirically).

In operation 430, recent and global usage patterns may be determined. For example, the measured current may be appended to a vector of recent current measurements (e.g., current measurements over the last x hours). In some embodiments, the recent current measurement may be filtered (for example using a moving-average or other filter) prior to appending the measurement of the current to the vector of recent current measurements. A global usage pattern may be determined from the vector of recent current measurements by taking an average (e.g., arithmetic mean) of the vector of recent current measurements, and storing this taken average in a vector of recent vector averages. The most recent average is representative of the average usage rate in the past x hours and represents the global pattern of the data at the present point in time. Local changes in the usage pattern may also be determined in operation 430, for example by fitting a linear regression curve to the past y values from vector of recent vector averages. In some embodiments, y≤x/2.

A predicted future usage rate is determined from the linear regression curve in operation 440. For example, a usage rate at a future point in time may be determined from a weighted average of an extrapolated point on the linear regression curve at a time (t+y) and the average of the vector of recent current measurements. In other words, the predicted future usage rate may be taken from a weighted average of a long-term global usage pattern and a recent short-term local usage pattern.

In operation 450, a correction factor may be applied to the predicted future usage rate determined in operation 440. For example, over a period of time (e.g., z hours), an actual usage of energy may be measured by the battery monitoring device 25. This actual usage of energy may be compared to the number of predicted used amp-hours over the same period of time. For example, a prediction may be made a time T₀ for amp-hour usage over a period of time from T₀ to T₁ (e.g., a period of z hours), and at T₁ the predicted amp-hour usage over the period of time from T₀ to T₁ may be compared with the actual usage over the period of time from T₀ to T₁. A calculated difference between the predicted usage over the period of time from T₀ to T₁ and the actual usage of the period of time from T₀ to T₁ may be used to adjust the newly predicted usage rate. This may be performed using Equation (5), below:

$${I}_{p r d} = {I}_{prd 1} + α * \frac{e}{z} \qquad ( 5 )$$

In Equation (5), I_{prd1} is the newly predicted usage rate from operation 440, e is the calculated difference between the predicted usage over the period of time from T₀ to T₁ and the actual usage of the period of time from T₀ to T₁, z is the length of the period of time from T₀ to T₁, and alpha (α) is an adjustable self-learning rate with a value between zero and one (e.g., 0≤α≤1). In some embodiments, the correction factor may only be periodically determined and/or periodically applied, for example to preserve computational resources and/or to limit vacillating behavior in the predicted future rate, e.g., from over and under correcting.

An initial prediction of the remaining time in discharge of the battery 20, or a previous prediction of the remaining time in discharge of the battery 20, may be updated in operation 460 based on the results of operations 420 and 450, that is, using the new estimated capacity of the battery 20 and the predicted future usage rate that has been periodically corrected. Additionally and/or alternatively in operation 460, a prediction of the remaining time to charge may be updated, as the current flowing to the battery 20 may result in decreased charge in the battery 20, decreasing the remaining capacity. For example, the new estimated capacity of the battery 20 may be used to calculate a new time to charge the battery 20. Accordingly, the initial prediction of the remaining time to charge the battery 20, or a previous prediction of the remaining time to charge the battery 20, may be updated in operation 460.

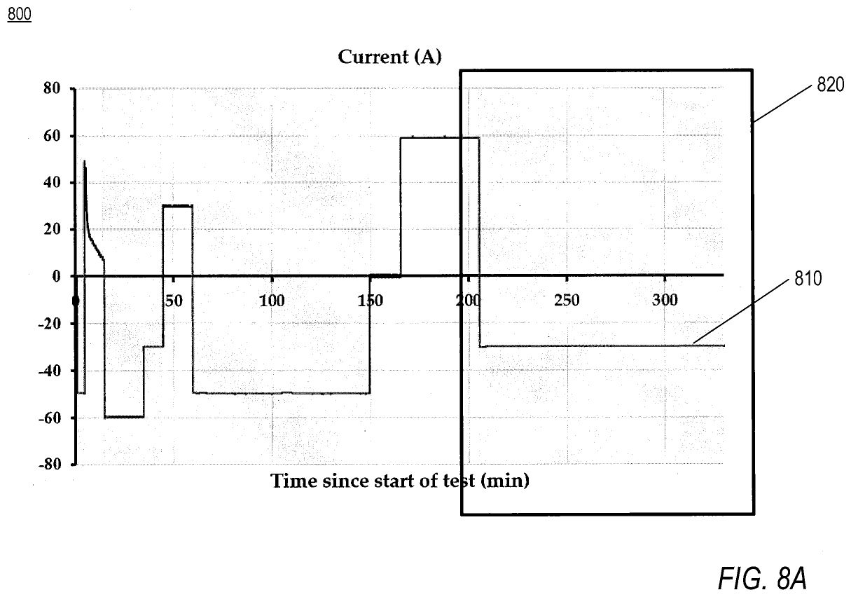

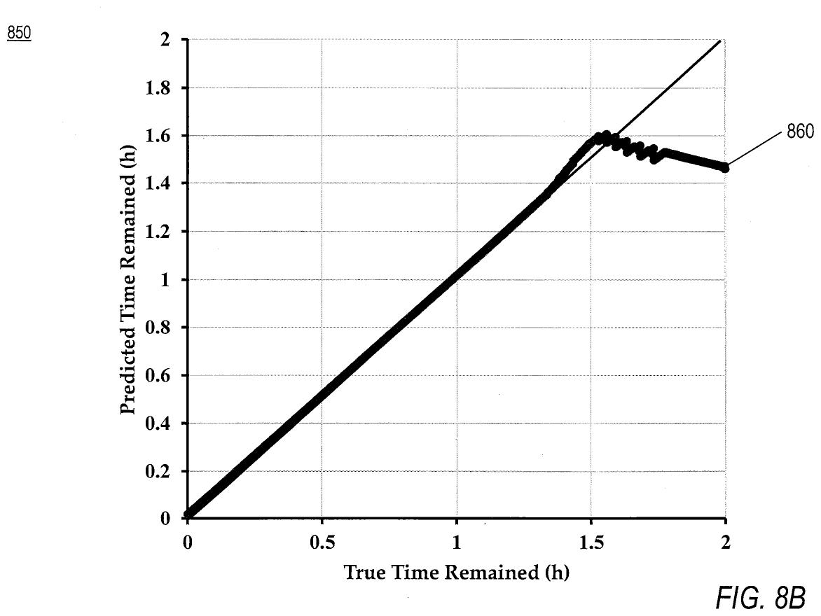

An example performance of the method 400 of FIG. 4 is illustrated in FIGS. 8A and 8B. As seen in plot 800 of FIG. 7A, a battery (e.g., the battery 20) may be discharged over a period of time, resulting in curve 810. During early portions of the discharge, e.g., at periods 812 and 814, the battery may be discharged at various rates (e.g., approximately 60 A at period 812 and approximately 50 A at period 814). FIG. 8B is a plot 850 of estimated time remaining vs. true time remaining at points during a portion 820 of plot 800 of FIG. 8A. In FIG. 8B, time is increasing toward the origin along the line y=x, and thus an ideal prediction system would result in y=x at all given points in time (e.g., an ideal predictive system would estimate 4 hours of remaining discharge at a time when there are actually 4 hours remaining in discharge). As illustrated by curve 860, the method 400 of FIG. 4 predicts a lower remaining time to discharge initially (approximately 1.4 hours remaining) at the beginning of period 820, based on the larger discharge currents at periods 812 and 814. As the battery monitoring system 25 determines that the predicted future usage rate is in error (e.g., at operation 440) the battery monitoring system 25 applies a correction factor, resulting in movement toward the curve y=x.

FIG. 5 is a flowchart of an example method 500 for performing calibration of variables, such as a SOC of a battery, used in monitoring the battery 20 according to some embodiments of the present inventive concepts. During operation 510, the current may be determined to be approximately zero or some value other than zero. For example, if the measured current is greater than the second current threshold −|I_{MIN}| and less than the first current threshold |I_{MIN}|, but is not zero, then it may be that the battery 20 is either minimally charging or discharging, such that no significant changes to the measured, estimated, or predicted values of the properties of the battery 20 are occurring. Accordingly, if the measured current is greater than the second current threshold −|I_{MIN}| and less than the first current threshold |I_{MIN}|, but is not zero (e.g., NO branch from operation 510), then conditions may not be appropriate for calibration and the method of FIG. 5 may end (for example by returning to the method of FIG. 2).

However, if the current is zero (e.g., YES branch from operation 510), then a timer or other counter value may be incremented in operation 520 until a period of time has elapsed. As discussed above, the length of the period of time may be dependent on the type or chemical properties of the battery 20, and may be (as an example) between 1-4 hours to permit relaxation of the battery 20. In some embodiments, this time may improve accuracy in determination of the SOC of the battery 20, as charge may distribute (e.g., evenly distribute) through the internal chemistry of the battery 20. If the period of time has not elapsed (e.g., NO branch from operation 520), then conditions may not be appropriate for calibration and the method of FIG. 5 may end (for example by returning to the method of FIG. 2).

If the period of time has elapsed (e.g., YES branch from operation 520) then a calibrated SOC of the battery 20 may be determined based on a measurement of an open circuit voltage (OCV) after a period of time where the battery 20 is idle. From the open circuit voltage, the initial SOC may be determined, for example using a curve or relationship between SOC and OCV. The calibrated SOC determined in this manner may then be stored in a memory device. Additional battery properties may be determined or estimated from the calibrated SOC. Such properties may include, in some embodiments, a remaining capacity of the battery (in units of Ah). The remaining capacity of the battery 20 may be determined from a product of the initial SOC with a nominal capacity of the battery 20, which may be retrieved from a memory device.

In operation 540, the timer incremented in operation 520 may be reset. Optionally, in operation 550, predicted or estimated values of properties of the battery 20 may be reset in favor of estimated or predicted values based on the calibrated SOC. For example, a prediction of the remaining time to charge may be determined from the calibrated SOC and a default time to completely charge the battery 20, as provided from a manufacturer of the battery 20 and/or based on empirical data collected for the battery 20 or the type of the battery 20. A calibrated prediction of the remaining time to discharge the battery 20 may be determined from the initial SOC and a nominal usage rate (in units of current) for an application (e.g., Class 1 electric rider trucks, Class 2 electric narrow isle trucks and Class 3 electric hand trucks). As discussed above, application may be provided as input to the battery monitoring device 25, or a default application (and hence a default nominal usage rate) may be used in the calibration method 500.

In some embodiments, the calibration method 500 of FIG. 5 may be performed every time that the battery 20 is fully charged.

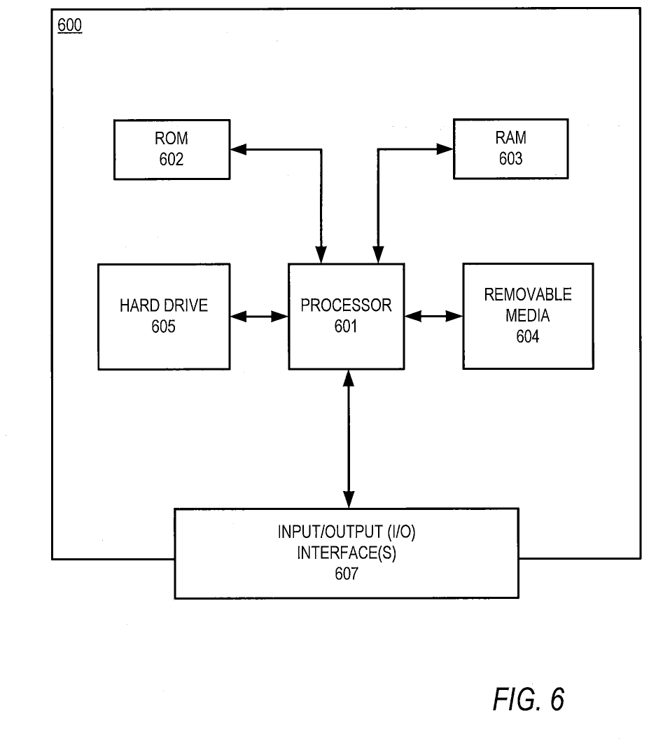

FIG. 6 illustrates various components of a computing device 600 which may be used to implement one or more of the devices herein, including the battery monitoring device 25, the database 80, and/or the computing devices 90, 95 of FIG. 1. FIG. 6 illustrates hardware elements that can be used in implementing any of the various computing devices discussed herein. In some aspects, general hardware elements may be used to implement the various devices discussed herein, and those general hardware elements may be specially programmed with instructions that execute the algorithms discussed herein. In special aspects, hardware of a special and non-general design may be employed (e.g., ASIC or the like). Various algorithms and components provided herein may be implemented in hardware, software, firmware, or a combination of the same.

A computing device 600 may include one or more processors 601, which may execute instructions of a computer program to perform any of the features described herein. The instructions may be stored in any type of computer-readable medium or memory, to configure the operation of the processor 601. For example, instructions may be stored in a read-only memory (ROM) 602, random access memory (RAM) 603, removable media 604, such as a Universal Serial Bus (USB) drive, compact disk (CD) or digital versatile disk (DVD), floppy disk drive, or any other desired electronic storage medium. Instructions may also be stored in an attached (or internal) hard drive 605. The computing device 600 may be configured to provide output to one or more output devices (not shown) such as printers, monitors, display devices, and so on, and receive inputs, including user inputs, via input devices (not shown), such as a remote control, keyboard, mouse, touch screen, microphone, or the like. The computing device 200 may also include input/output interfaces 607 which may include circuits and/or devices configured to enable the computing device 600 to communicate with external input and/or output devices (e.g., the battery 20, network devices of the network 50) on a unidirectional or bidirectional basis. The components illustrated in FIG. 6 (e.g., processor 601, ROM storage 602) may be implemented using basic computing devices and components, and the same or similar basic components may be used to implement any of the other computing devices and components described herein. For example, the various components herein may be implemented using computing devices having components such as a processor executing computer-executable instructions stored on a computer-readable medium, as illustrated in FIG. 6.

The various inventive concepts provide several distinctive advantages. First, the inventive concepts provided herein provide a comprehensive algorithm for estimating the present state of charge of a battery and of predicting a future state of charge of the battery in both charge and discharge. The inventors have recognized that prior systems did not provide such comprehensiveness. For example, some previous systems provided only neural networks for state of charge estimation without prediction, or proposed algorithms that predict capacity or runtime in discharge only and not charge.

Second, the present inventive concepts provide prediction of a future usage pattern of a battery in discharge based on extraction of both a global or long term usage pattern as well as local or short term changes in the usage pattern occurring in the near past. The inventors have recognized that previous systems usually only use the average usage pattern in the past or the present rate of discharge as an indication of the future usage pattern; or alternatively information from the battery voltage is used to predict the remaining run time of the battery system.

Third, the inventive concepts herein improve the prediction accuracy of the remaining discharge time by adding a self-learning feature, as discussed above. For example, the algorithm is “penalized” when past prediction error occurs, which may enforce faster adaptation to a new usage pattern. Advantageously, in some embodiments the self-learning feature may use only a relatively small amount of memory storage to store data representing only a few seconds to minutes of data to provide the correction factor, and may be computationally efficient.

Fourth, predicting time remaining to charge in both constant current and constant voltage phases may include usage of models of non-linear behavior in both the constant current and constant voltage stages, as well as usage of an analytical model to predict temporal changes in current in the constant voltage stage of charging. It is submitted that the topic of predicting the time remaining to full charge in battery systems has received little attention by the field, with progress limited to systems that use lookup tables based on the battery current at a point in time. The inventive concepts, in contrast, provide improved accuracy over such systems.

The inventive concepts provided by the present disclosure have been be described above with reference to the accompanying drawings and examples, in which examples of embodiments of the inventive concepts are shown. The inventive concepts provided herein may be embodied in many different forms than those explicitly disclosed herein, and the present disclosure should not be construed as limited to the embodiments set forth herein. Rather, the examples of embodiments disclosed herein are provided so that this disclosure will be thorough and complete, and will fully convey the scope of the inventive concepts to those skilled in the art. Like numbers refer to like elements throughout.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the specification and relevant art and should not be interpreted in an idealized or overly formal sense unless expressly so defined herein. Well-known functions or constructions may not be described in detail for brevity and/or clarity.

Some of the inventive concepts are described herein with reference to block diagrams and/or flowchart illustrations of methods, apparatus (systems) and/or computer program products, according to embodiments of the inventive concepts. It is understood that one or more blocks of the block diagrams and/or flowchart illustrations, and combinations of blocks in the block diagrams and/or flowchart illustrations, can be implemented by computer program instructions. These computer program instructions may be provided to a processor of a general purpose computer, special purpose computer, and/or other programmable data processing apparatus to produce a machine, such that the instructions, which execute via the processor of the computer and/or other programmable data processing apparatus, create means for implementing the functions/acts specified in the block diagrams and/or flowchart block or blocks.

These computer program instructions may also be stored in a computer-readable memory that can direct a computer or other programmable data processing apparatus to function in a particular manner, such that the instructions stored in the computer-readable memory produce an article of manufacture including instructions which implement the function/act specified in the block diagrams and/or flowchart block or blocks.

The computer program instructions may also be loaded onto a computer or other programmable data processing apparatus to cause a series of operational steps to be performed on the computer or other programmable apparatus to produce a computer-implemented process such that the instructions which execute on the computer or other programmable apparatus provide steps for implementing the functions/acts specified in the block diagrams and/or flowchart block or blocks.

Accordingly, the inventive concepts may be embodied in hardware and/or in software (including firmware, resident software, micro-code, etc.). Furthermore, embodiments of the present inventive concepts may take the form of a computer program product on a computer-usable or computer-readable non-transient storage medium having computer-usable or computer-readable program code embodied in the medium for use by or in connection with an instruction execution system.

The computer-usable or computer-readable medium may be, for example but not limited to, an electronic, optical, electromagnetic, infrared, or semiconductor system, apparatus, or device. More specific examples (a non-exhaustive list) of the computer-readable medium would include the following: an electrical connection having one or more wires, a portable computer diskette, a random access memory (RAM), a read-only memory (ROM), an erasable programmable read-only memory (EPROM or Flash memory such as an SD card), an optical fiber, and a portable compact disc read-only memory (CD-ROM).

The terms first, second, etc. may be used herein to describe various elements, but these elements should not be limited by these terms. These terms are only used to distinguish one element from another. For example, a first element could be termed a second element, and, similarly, a second element could be termed a first element, without departing from the scope of the present inventive concepts. As used herein, the term “and/or” includes any and all combinations of one or more of the associated listed items. As used herein, the singular forms “a”, “an” and “the” are intended to include the plural forms as well, unless the context clearly indicates otherwise. It should be further understood that the terms “comprises,” “comprising,” “includes,” and/or “including” when used herein, specify the presence of stated features, operations, elements, and/or components, but do not preclude the presence or addition of one or more other features, operations, elements, components, and/or groups thereof.

When an element is referred to as being “on” another element, it can be directly on the other element or intervening elements may also be present. In contrast, when an element is referred to as being “directly on” another element, there are no intervening elements present. When an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (i.e., “between” versus “directly between”, “adjacent” versus “directly adjacent”, etc.).

The terminology used herein is for the purpose of describing particular embodiments only and is not intended to be limiting of the present disclosure.

Aspects and elements of all of the embodiments disclosed above can be combined in any way and/or combination with aspects or elements of other embodiments to provide a plurality of additional embodiments. Although a few exemplary embodiments of the inventive concepts have been described, those skilled in the art will readily appreciate that many modifications are possible in the exemplary embodiments without materially departing from the novel teachings and advantages of the inventive concepts provided herein. Accordingly, all such modifications are intended to be included within the scope of the present application as defined in the claims.

What is claimed is:

1. A method comprising:
measuring one or more properties of a battery;
determining a charging status of the battery based on the measured one or more properties; and
updating one or more predictions of properties of the battery based on the determined charging status of the battery, wherein the one or more predictions comprises a prediction of a remaining time to charge the battery and/or a prediction of a remaining time to discharge the battery, resulting in updated one or more predictions of the properties of the battery.

2. The method of claim 1, further comprising:
performing one or more actions based on the updated one or more predictions of the properties of the battery, wherein the performed one or more actions comprises displaying the updated one or more predictions on a display device of a vehicle in which the battery is installed.

3. The method of claim 1, further comprising initializing the one or more predictions of the properties of the battery prior to updating the one or more predictions of the properties of the battery, wherein initializing the one or more predictions of the predictions comprises calculating the properties of the battery based on predetermined values.

4. The method of claim 1, wherein measuring the one or more properties comprises measuring a current, a voltage, and a temperature of the battery, and wherein updating the one or more predictions comprises updating the prediction of the remaining time to charge the battery, and wherein updating the prediction of the remaining time to charge the battery comprises:
calculating a charge efficiency based on the measured amount of current and the measured temperature of the battery;
estimating a state of charge based on the calculated charge efficiency;
determining whether the battery is in a constant current charging stage or a constant voltage charging stage; and
updating the prediction of the remaining time to charge the battery using a first operation based on determining that the battery is in the constant current charging stage or updating the prediction of the remaining time to charge the battery using a second operation based on determining that the battery is in the constant voltage charging stage.

5. The method of claim 4, wherein the first operation comprises selecting a constant current pre-trained multi-variable model and applying the selected constant current pre-trained multi-variable model to the measured one or more properties of the battery.

6. The method of claim 5, wherein the first operation further comprises selecting a constant voltage pre-trained multi-variable model and applying the selected constant voltage pre-trained multi-variable model to the measured one or more properties of the battery.

7. The method of claim 4, wherein the first operation comprises selecting a constant voltage pre-trained multi-variable model and applying the selected constant voltage pre-trained multi-variable model to the measured one or more properties of the battery, and wherein the second operation comprises calculating a refinement to an output of the selected constant voltage pre-trained multi-variable model and applying the refinement to the output of the selected constant voltage pre-trained multi-variable model.

8. The method of claim 1, wherein measuring the one or more properties comprises measuring a current, a voltage, and a temperature of the battery, and wherein updating the one or more predictions comprises updating the prediction of the remaining time to discharge the battery, and wherein updating the prediction of the remaining time to discharge the battery comprises:
estimating a state of charge based on the measured current;
determining a recent usage pattern and a global usage pattern;
predicting a future usage rate based on the recent usage pattern and the global usage pattern; and
updating the prediction of the remaining time to discharge the battery based on the predicted future usage rate.

9. The method of claim 8, wherein predicting the future usage rate based on the recent usage pattern and the global usage pattern comprises calculating a weighted average of the recent usage pattern and the global usage pattern.

10. The method of claim 8, wherein predicting the future usage rate based on the recent usage pattern and the global usage pattern comprises applying a periodically determined correction factor to an uncorrected predicted future usage rate.

11. The method of claim 10, wherein the periodically determined correction factor is based on a calculated difference between a predicted usage of the battery over a period of time and an actual usage of the battery over the period of time.

12. An apparatus comprising:
a processor; and
memory storing computer-readable instructions that, when executed by the processor, cause the processor to perform operations comprising:
measuring one or more properties of a battery;
determining a charging status of the battery based on the measured one or more properties; and
updating one or more predictions of properties of the battery based on the determined charging status of the battery, wherein the one or more predictions comprises a prediction of a remaining time to charge the battery and/or a prediction of a remaining time to discharge the battery, resulting in updated one or more predictions of the properties of the battery.

13. The apparatus of claim 12, further comprising the battery.

14. The apparatus of claim 12, wherein the memory stores further computer-readable instructions that, when executed by the processor, cause the processor to perform further operations comprising:
performing one or more actions based on the updated one or more predictions of the properties of the battery, wherein the performed one or more actions comprises displaying the updated one or more predictions on a display device of a vehicle in which the battery is installed.

15. The apparatus of claim 12, wherein measuring the one or more properties comprises measuring a current, a voltage, and a temperature of the battery, and wherein updating the one or more predictions comprises updating the prediction of the remaining time to charge the battery, and wherein updating the prediction of the remaining time to charge the battery comprises:
calculating a charge efficiency based on the measured amount of current and the measured temperature of the battery;
estimating a state of charge based on the calculated charge efficiency;
determining whether the battery is in a constant current charging stage or a constant voltage charging stage; and
updating the prediction of the remaining time to charge the battery using a first operation based on determining that the battery is in the constant current charging stage or updating the prediction of the remaining time to charge the battery using a second operation based on determining that the battery is in the constant voltage charging stage.

16. The apparatus of claim 12, wherein measuring the one or more properties comprises measuring a current, a voltage, and a temperature of the battery, and wherein updating the one or more predictions comprises updating the prediction of the remaining time to discharge the battery, and wherein updating the prediction of the remaining time to discharge the battery comprises:
estimating a state of charge based on the measured current;
determining a recent usage pattern and a global usage pattern;
predicting a future usage rate based on the recent usage pattern and the global usage pattern; and
updating the prediction of the remaining time to discharge the battery based on the predicted future usage rate.

17. A battery monitoring system, comprising:
a battery;
a battery monitoring apparatus communicatively coupled to the battery, wherein the battery monitoring apparatus is configured to perform operations comprising:
measuring one or more properties of a battery;
determining a charging status of the battery based on the measured one or more properties; and
updating one or more predictions of properties of the battery based on the determined charging status of the battery, wherein the one or more predictions comprises a prediction of a remaining time to charge the battery and/or a prediction of a remaining time to discharge the battery, resulting in updated one or more predictions of the properties of the battery.

18. The system of claim 17, wherein measuring the one or more properties comprises measuring a current, a voltage, and a temperature of the battery, and wherein updating the one or more predictions comprises updating the prediction of the remaining time to charge the battery, and wherein updating the prediction of the remaining time to charge the battery comprises:
calculating a charge efficiency based on the measured amount of current and the measured temperature of the battery;
estimating a state of charge based on the calculated charge efficiency;
determining whether the battery is in a constant current charging stage or a constant voltage charging stage; and
updating the prediction of the remaining time to charge the battery using a first operation based on determining that the battery is in the constant current charging stage or updating the prediction of the remaining time to charge the battery using a second operation based on determining that the battery is in the constant voltage charging stage.

19. The system of claim 17, wherein measuring the one or more properties comprises measuring a current, a voltage, and a temperature of the battery, and wherein updating the one or more predictions comprises updating the prediction of the remaining time to discharge the battery, and wherein updating the prediction of the remaining time to discharge the battery comprises:
estimating a state of charge based on the measured current;
determining a recent usage pattern and a global usage pattern;
predicting a future usage rate based on the recent usage pattern and the global usage pattern; and
updating the prediction of the remaining time to discharge the battery based on the predicted future usage rate.

20. The system of claim 17, further comprising at least one computing device located remotely from the battery monitoring apparatus and configured to communicate with the battery monitoring apparatus over a network, wherein the battery monitoring apparatus is configured to transmit the updated one or more predictions of the properties of the battery to the at least one computing device via the network, and wherein the at least one computing device is configured to receive the updated one or more predictions of the properties of the battery and perform one or more actions based thereon.
